(19) United States
(12) Patent Application Publication
(10) Pub. No.: US 2011/0272746 A1
(43) Pub. Date: Nov. 10, 2011

(54) SOLID STATE IMAGING DEVICE THAT INCLUDES A CONTACT PLUG USING TITANIUM AS A CONTACT MATERIAL, AND MANUFACTURING METHOD THEREOF

(76) Inventor: Noriaki SUZUKI, Kyoto (JP)

(21) Appl. No.: 13/009,588

(22) Filed: Jan. 19, 2011

(30) Foreign Application Priority Data
May 10, 2010 (JP) 2010-108427

(51) Int. Cl. H01L 27/148; H01L 31/18

(52) U.S. Cl. 257/222; 438/76; 257/E31.124; 257/E27.15

(57) ABSTRACT

The present invention provides a solid state imaging device and a manufacturing method thereof that lowers contact resistance and suppresses dark current, even when wirings and contact plugs are reduced in size. A solid state imaging device 1 includes wirings 24 and a transfer electrode film 102 that are connected to each other by lower contact plugs A in one layer and upper contact plugs B in another layer. A titanium silicide film 105 is formed at a bottom of each lower contact plug A. The upper contact plugs B do not include any titanium silicide, and are connected to the lower contact plugs A via a tungsten film 107 that is an intermediate wiring layer. Neither of the upper and lower contact plugs A and B includes pure titanium. Intralayer lens films 127 above photodiodes 121 in an imaging pixel region are formed after the lower contact plugs A are formed.

### TECHNICAL FIELD

The disclosure of Japanese Patent Application No. 2010-108427 filed including specification, drawings and claims is incorporated herein by reference in its entirety.

The present invention relates to a solid state imaging device that includes a contact plug using titanium as a contact material, and a manufacturing method thereof.

### BACKGROUND ART

As multi-functionalization and integration of solid state imaging devices are promoted, there is a demand for wirings and contact plugs thereof to be smaller in size. Each of the contact plugs is formed by disposing a filling, which is made of a contact material, in a contact hole. To reduce the sizes of wirings and contact plugs, titanium (Ti) may be used as a contact material of the contact plugs so as to lower resistance. Titanium is also used in CCD (Charge Coupled Device) solid state imaging devices, due to high resolution and reduction in a chip size. Specifically, titanium is used as a contact material of contact plugs that connect a silicon substrate to polysilicon wirings.

Here, each CCD solid state imaging device is manufactured through a process including the following steps: introducing impurities into the silicon substrate and forming a charge transfer channel, a channel separation area, a diffusion layer such as a floating diffusion (FD); laminating an insulating film and a polysilicon layer on the silicon substrate; and forming contact plugs for the polysilicon layer and the diffusion layer, and further forming metal wirings.

At a relatively late stage of the manufacturing process of the CCD solid state imaging devices, an anneal treatment is performed in a gas atmosphere such as hydrogen. The anneal treatment is performed to terminate dangling bonds with use of hydrogen generated in the gas atmosphere or in the laminated films, so as to reduce interface state density. The dangling bonds are generated at an interface between the silicon substrate and a gate insulating film during the manufacturing process. The anneal treatment is important in analog devices such as the CCD solid state imaging devices, since an energy level of the dangling bonds affects the device performance more significantly, compared to digital devices such as memory devices and logic circuits.

In the case of using titanium as a contact material of the contact plugs, however, the titanium traps the hydrogen that tries to diffuse toward the interface between the silicon substrate and the gate insulting film, during the anneal treatment. This is caused by the property of titanium that traps hydrogen. As a result, the dangling bonds at the interface between the silicon substrate and the gate insulating film are not terminated efficiently. If this problem with the dangling bonds occurs in a CCD solid state imaging device, dark current will increase in an imaging pixel or a charge transfer unit, due to the titanium in a wiring section.

To address such a problem, Patent Literature 1 discloses a technique pertaining to a titanium silicide contact. The following briefly describes the technique disclosed in Patent Literature 1, with reference to FIGS. 1A and 1B.

According to the technique disclosed in Patent Literature 1, a silicon oxide film 901, a transfer electrode film 902, an interlayer insulating film 903, a polysilicon wiring 904, and a silicon oxide film 905 are laminated on a silicon substrate 900 in the stated order, as shown in FIG. 1A. Then, an opening that reaches the polysilicon wiring 904 is formed. Next, a titanium nitride film 906 is formed on an inner surface of the opening, and a titanium silicide film 907 is formed at the bottom of the opening. Furthermore, tungsten is filled inside the opening to form a tungsten wiring 908. Then, an upper layer 909 is laminated on the titanium nitride film 906 and the tungsten wiring 908.

The tungsten wiring 908 in FIG. 1A is formed in the following manner. First, a titanium film is formed on an inner surface of a contact hole. Then, an anneal treatment is performed on the titanium film so as to form a C49 phase titanium silicide film at a bottom of the contact hole. After an unreacted titanium film is removed, a titanium nitride film is formed on the inner surface of the contact hole. Then, an anneal treatment is performed again so that the C49 phase titanium silicide film is transitioned to a C54 phase titanium silicide film 907. In the manufacturing process of a CCD solid state imaging device, an anneal treatment is further performed afterward in a gas atmosphere such as hydrogen. This reduces the interface state density and contact resistance.

### CITATION LIST

### Patent Literature

### [Patent Literature 1]

Japanese Patent Application Publication No. 2007-335554

### SUMMARY OF INVENTION

### Technical Problem

However, if the technique disclosed in Patent Literature 1 is employed, the anneal treatment performed at the time of forming the titanium silicide film 907 may damage the optical films in an imaging pixel region, etc., which are formed before the formation of the titanium silicide film 907. Specifically, the CCD solid state imaging device has the following structure in the imaging pixel region, as shown in FIG. 1B. A photodiode 911 and charge transfer channels 912 are formed in the silicon substrate 900. The silicon substrate 900 is covered by a gate insulating film 913. Then, the following films are formed on the gate insulating film 913: the transfer electrode film 902; an insulating film 914; a light-shielding film 915; interlayer insulating films 916 and 918; intralayer lens films 917 and 919; a color filter film 920; and a top lens film 921.

In the aforementioned structure of the imaging pixel region, the intralayer lens films 917 and 919, for example, are formed using a plasma CVD method, and have low resistance to the heat produced by the anneal treatment performed for forming the titanium silicide film 907. Therefore, when the anneal treatment is performed to form the titanium silicide film 907, films having low heat resistance, such as the intralayer lens films 917 and 919, may be peeled off, or the film stress thereof may remain, leading to an increase in dark current.

Note that the films having low heat resistance may include a silicon nitride film, a silicon oxide film, a silicon oxynitride film, etc., in addition to the films formed using the plasma CVD method. Also, the metals that trap hydrogen at the time of an anneal treatment in a hydrogen atmosphere may include cobalt and nickel, in addition to titanium mentioned above.

The present invention provides a solid state imaging device and a manufacturing method thereof that lower contact resistance and suppress dark current, even when wirings and contact plugs are reduced in size.

### Solution to Problem

In order to solve the above problems, the present invention employs the following structure.

The present invention provides a solid state imaging device having, with respect to a silicon substrate, a pixel region and a peripheral region adjacent thereto. The pixel region includes: a plurality of photoelectric conversion units formed in the silicon substrate; and a plurality of layers laminated on the silicon substrate, and the peripheral region includes: a layer including silicon formed above the silicon substrate; a plurality of insulating layers formed above the layer including silicon; and a wiring layer made of a metal material and formed above the insulating layers. Also, the wiring layer and either one of the silicon substrate and the layer including silicon are connected to each other by a contact plug group passing through the insulating layers.

Furthermore, in the solid state imaging device according to the present invention, the contact plug group includes first and second contact plugs, the first contact plug located closer to the silicon substrate than the second contact plug, the first contact plug is a filling that is disposed in a first contact hole, and that is made of a first contact material, the second contact plug is a filling that is disposed in a second contact hole, and that is made of a second contact material. Here, the first contact material includes a metal silicide and a first high melting point metal, the metal silicide formed at a bottom of the first contact plug and including one selected from the group consisting of titanium, cobalt, and nickel. The first high melting point metal is other than a pure metal of titanium, cobalt, or nickel.

Also, the second contact material is free of the metal silicide and includes a second high melting point metal. The second high melting point metal is other than a pure metal of titanium, cobalt, or nickel.

The solid state imaging device according to the present invention is characterized in that the plurality of layers in the pixel region include a low heat-resistance layer whose resistance to heat produced by an anneal treatment pertaining to formation of the metal silicide is lower than a predetermined value, and the low heat-resistance layer is selectively arranged higher than the first contact plug with respect to the silicon substrate, in a lamination order of the layers.

Note that the aforementioned “higher . . . in a lamination order” does not indicate absolute “higher” in spatial perception, but indicates “higher (i.e., subsequent)” in the lamination order of the layers. In other words, “arranged higher . . . in a lamination order” indicates that the layer is arranged “higher” than the first contact plug in the lamination order by being formed after the first contact plug is formed.

Also, the present invention provides a manufacturing method of a solid state imaging device comprising the steps of: forming a pixel region that includes a plurality of photoelectric conversion units; and forming a peripheral region adjacent to a part of the silicon substrate designated for the pixel region, the peripheral region including first and second insulating layers and a wiring layer made of a metal material. In the manufacturing method of the solid state imaging device according to the present invention, the peripheral region forming step at least includes the following first to sixth substeps.

In the first substep, the first insulating layer is formed above the silicon substrate. Then, a first contact hole is formed in a part of the first insulating layer.

In the second substep, a titanium layer is formed on an inner surface of the first contact hole.

In the third substep, a titanium silicide layer is formed at a bottom of the first contact hole by performing an anneal treatment on the titanium layer. Then, a first contact plug is formed by disposing a first high melting point metal in the first contact hole.

In the fourth substep, the second insulating layer is formed on the first insulating layer in which the first contact plug has been formed. Then, a second contact hole is formed in a part of the second insulating layer that is to be connected to the first contact plug.

In the fifth substep, a second contact plug is formed by disposing, in the second contact hole, a second high melting point metal including at least one selected from the group consisting of tungsten, tungsten nitride, and titanium nitride.

In the sixth substep, the wiring layer is formed in contact with the second contact plug.

Meanwhile, the pixel region forming step at least includes the following first and second substeps.

In the first substep of the pixel region forming step, the plurality of photoelectric conversion units are formed in the silicon substrate.

In the second substep of the pixel region forming step, a plurality of layers are formed on the silicon substrate after the photoelectric conversion units are formed, the plurality of layers including a low heat-resistance layer whose resistance to heat produced by the anneal treatment in the third substep of the peripheral region forming step is lower than a predetermined value. The low heat-resistance layer is formed after the photoelectric conversion units are formed and before the second contact plug is formed.

In the manufacturing method of the solid state imaging device according to the present invention, the first high melting point metal constituting the first contact plug is free of pure titanium, and the second high melting point metal constituting the second contact plug is free of titanium silicide and pure titanium.

Also, the manufacturing method of the solid state imaging device according to the present invention has the following features. That is, in the substep of forming the plurality of layers in the pixel region forming step, at least the low heat-resistance layer is formed after the anneal treatment in the third substep of the peripheral region forming step.

### Advantageous Effects of Invention

In the solid state imaging device according to the present invention, the second contact material used for the second contact plug includes the second high melting point metals (e.g., tungsten, tungsten nitride, titanium nitride, and annealed titanium nitride, etc.). Since the wiring layer is made of a metal material, and the second contact plug includes the second high melting point metal, which is also a metal material, contact resistance there between is low. Also, since the metal silicide is formed at the bottom of the first contact plug, it is possible to connect the first contact plug and either one of the silicon substrate and the layer including silicon (silicon-based layer) while lowering contact resistance by means of reduction and silicidation of a metal such as titanium. This also enables lowering resistance even when the wirings and the contact plugs are reduced in size.

Also, in a case where resistance is set according to prior art, the number of contact plugs to be formed can be reduced. As a result, the size of a chip can be reduced as well.

Furthermore, in the solid state imaging device according to the present invention, the metal silicide is formed at the bottom of the first contact plug, and each of the first and second high melting point metals, which are used as the contact materials of the first and second contact plugs, is other than a pure metal of titanium, cobalt, or nickel. This eliminates a problem of hydrogen being trapped at the time of an anneal treatment performed in a gas atmosphere such as hydrogen. As a result, in the solid state imaging device according to the present invention, dangling bonds generated at the interface between the silicon substrate and the gate insulating film during the manufacturing process can be effectively terminated by an anneal treatment in a hydrogen atmosphere. This ensures reduction in the interface state density. Consequently, the solid state imaging device according to the present invention achieves high device performance.

Furthermore, in the solid state imaging device according to the present invention, the low heat-resistance layer in the pixel region is selectively arranged higher than the first contact plug with respect to the silicon substrate, in the lamination order of the layers. Also, during the manufacturing process, the low heat-resistance layer is formed after the anneal treatment pertaining to formation of the titanium silicide layer at the bottom of the first contact hole. Therefore, the low heat-resistance layer is not damaged by the anneal treatment pertaining to formation of the metal silicide at the first contact hole. Specifically, the low heat-resistance layer is prevented from cracks, peeling, and film stress. As a result, the solid state imaging device according to the present invention eliminates problems such as an increase in dark current caused by the damage of the low heat-resistance layer in the pixel region.

Note that the aforementioned “selectively” indicates that the low heat-resistance layer is formed in a restrictive manner. Specifically, the low heat-resistance layer is formed higher than the first contact plug in the lamination order of the layers (i.e., the low heat-resistance layer is formed only after the first contact plug is formed).

As described above, the solid state imaging device according to the present invention lowers contact resistance and suppresses dark current, even when the wirings and the contact plugs are reduced in size.

The solid state imaging device according to the present invention may employ the following variations.

In the solid state imaging device according to the present invention, a top of the first contact plug and a bottom of the second contact plug may be connected to each other by an intermediate wiring layer provided in parallel with a main surface of the silicon substrate, and the intermediate wiring layer may include a third high melting point metal that is other than pure titanium. With the stated structure, the intermediate wiring layer is provided between the first and second contact plugs. This means that the second contact plug is laminated on the first contact plug with the intermediate wiring layer in between. In this way, the intermediate wiring layer absorbs variations in size and position during the manufacturing process, increasing a yield rate and flexibility in design during the manufacturing process.

Also, in the solid state imaging device according to the present invention, the pixel region may further include: a plurality of charge transfer channels, each of which is formed adjacent to the corresponding photoelectric conversion unit in the silicon substrate and transfers charge generated by the corresponding photoelectric conversion unit, and the layer including silicon may be a transfer electrode made of polysilicon, and is arranged above each charge transfer channel.

Furthermore, in the solid state imaging device according to the present invention, each of the first and second high melting point metals of the first and second contact plugs may include one selected from the group consisting of tungsten, tungsten nitride, titanium nitride, and annealed titanium nitride. This makes it possible to lower contact resistance since the wiring layer and each of the first and second high melting point metals are made of metal.

Also, in the solid state imaging device according to the present invention, the low heat-resistance layer may be resistant to a temperature lower than 650 degrees Celsius. A temperature to perform an anneal treatment in order to silicide a metal, such as titanium, is 650 degrees Celsius. However, according to the solid state imaging device of the present invention, the low heat-resistance layer is arranged higher than (i.e., subsequent to) the first contact plug with respect to the silicon substrate, in the lamination order of the films. Therefore, the low heat-resistance layer is not damaged by the anneal treatment although the heat-resistant temperature thereof is lower than 650 degrees Celsius.

Furthermore, in the solid state imaging device according to the present invention, the low heat-resistance layer may be formed using a plasma CVD method. Note that the present invention is not limited to the structure where the low heat-resistance layer is formed using the plasma CVD method.

Also, in the solid state imaging device according to the present invention, the wiring layer may be made of one of aluminum, copper, an aluminum alloy, and a copper alloy.

Furthermore, the manufacturing method of the solid state imaging device according to the present invention enables manufacturing of the solid state imaging device according to the present invention.

The manufacturing method of the solid state imaging device according to the present invention may adopt the following structure. That is, in the third substep of the peripheral region forming step, after forming the titanium silicide layer at the bottom of the first contact hole by the anneal treatment, unreacted titanium that has not been silicided is removed, and at least one of tungsten, tungsten nitride, and titanium nitride is disposed in the first contact hole as a contact material. With the stated structure, even if the anneal treatment is not performed appropriately, leaving some titanium unconsumed; the remaining titanium is removed thoroughly. This reliably eliminates a problem of hydrogen being trapped at the time of an anneal treatment that is subsequently performed in a gas atmosphere such as hydrogen. Accordingly, the interface state density between the silicon substrate and the gate insulating film is effectively reduced.

### BRIEF DESCRIPTION OF DRAWINGS

FIG. 1A is a schematic sectional view showing a structure of a wiring region of a solid state imaging device according to prior art.

FIG. 1B is a schematic sectional view showing a structure of an imaging pixel region of the solid state imaging device according to the prior art.

FIG. 2 is a schematic plan view showing a general structure of a solid state imaging device 1 according to Embodiment 1 of the present invention.

FIG. 3A is a schematic sectional view showing a structure of a wiring region 20 of the solid state imaging device 1, in which wirings 24 are arranged.

FIG. 3B is a schematic sectional view showing a structure of an imaging pixel region 10 of the solid state imaging device 1.

FIG. 4A is a schematic sectional view showing a structure of the wiring region 20 during the manufacturing process.

FIG. 4B is a schematic sectional view showing a structure of the imaging pixel region 10 during the manufacturing process.

FIG. 4C is a schematic sectional view showing a structure of the wiring region 20 during the manufacturing process.

FIG. 4D is a schematic sectional view showing a structure of the imaging pixel region 10 during the manufacturing process.

FIG. 5A is a schematic sectional view showing a structure of the wiring region 20 during the manufacturing process.

FIG. 5B is a schematic sectional view showing a structure of the imaging pixel region 10 during the manufacturing process.

FIG. 5C is a schematic sectional view showing a structure of the wiring region 20 during the manufacturing process.

FIG. 5D is a schematic sectional view showing a structure of the imaging pixel region 10 during the manufacturing process.

FIG. 6A is a schematic sectional view showing a structure of the wiring region 20 during the manufacturing process.

FIG. 6B is a schematic sectional view showing a structure of the imaging pixel region 10 during the manufacturing process.

FIG. 6C is a schematic sectional view showing a structure of the wiring region 20 during the manufacturing process.

FIG. 6D is a schematic sectional view showing a structure of the imaging pixel region 10 during the manufacturing process.

FIG. 7 is a schematic sectional view showing a structure of a wiring region in a solid state imaging device 2 according to Embodiment 2.

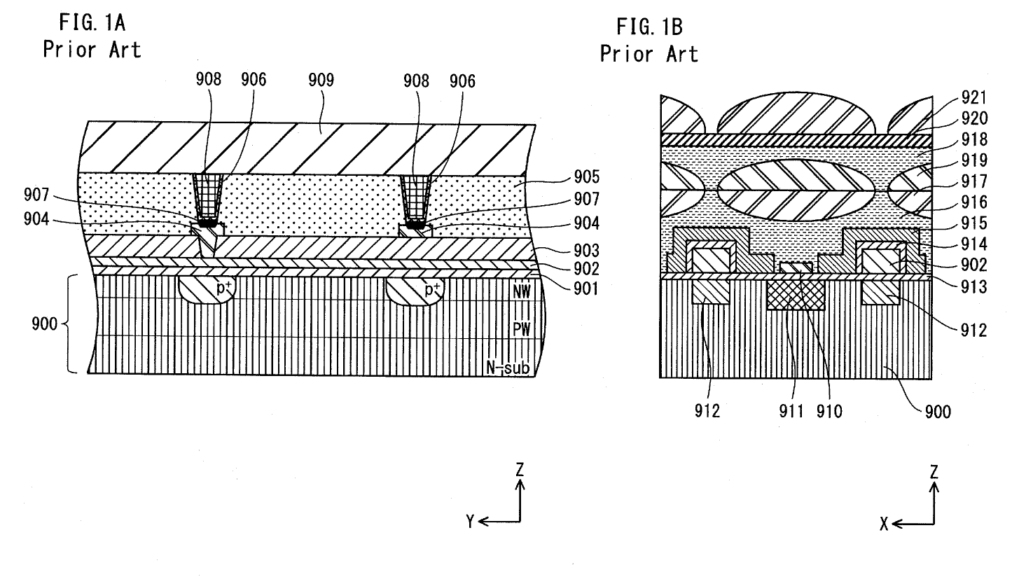

### DESCRIPTION OF EMBODIMENTS

The following describes embodiments of the present invention with reference to drawings. The embodiments described below are merely examples used to clearly describe the structure, operations, and effects of the present invention. Therefore, the present invention should not be limited to these embodiments other than with respect to the gist of the embodiments.

### Embodiment 1

### 1. General Structure of Solid State Imaging Device 1

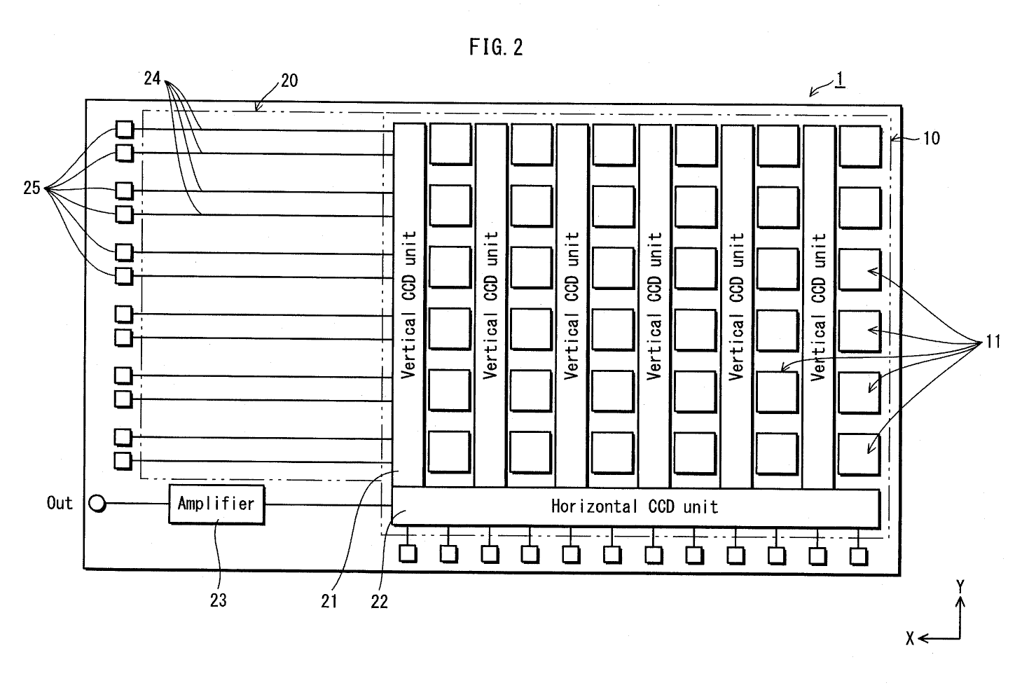

The following describes a general structure of a solid state imaging device 1 according to the present embodiment, with reference to FIG. 2. The present embodiment takes an example of an interline transfer CCD solid state imaging device.

As shown in FIG. 2, the solid state imaging device 1 includes a plurality of imaging pixels 11 which are arranged in a matrix in an X-Y plane direction. Between each column of the imaging pixels 11, a vertical transfer unit 21 is arranged that extends in the Y-axis direction. At the bottom of the vertical transfer units 21 in the Y-axis direction, a horizontal transfer unit 22 is arranged that extends in the X-axis direction. A region including the imaging pixels 11, the vertical transfer units 21, etc. is referred to as an imaging pixel region 10.

The horizontal transfer unit 22 is connected to an output amplifier 23. Transfer electrodes (not shown in FIG. 2) of the vertical transfer units 21 are connected to wirings 24. The wirings 24 are connected to electrode pads 25. The wirings 24 are provided to apply drive pulses to the transfer electrodes of the vertical transfer units 21.

Hereinafter, a region in which the wirings 24 are arranged is referred to as a wiring region 20.

### 2. Structure of Wiring Region 20

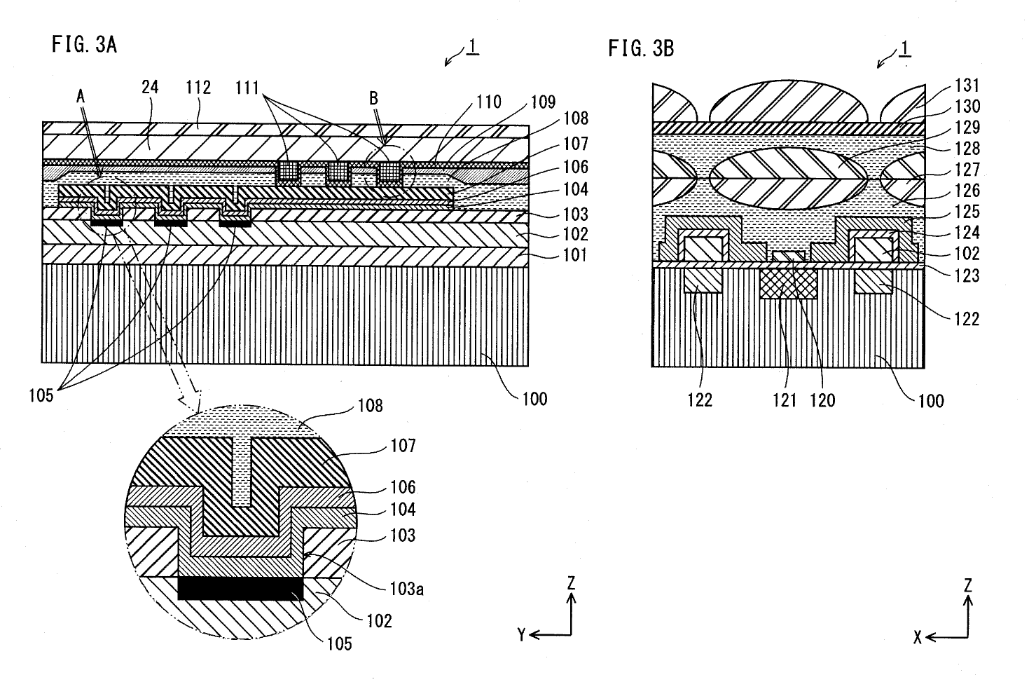

The following describes a structure of the wiring region 20 of the solid state imaging device 1, with reference to FIG. 3A.

As shown in FIG. 3A, a field insulating film 101, a transfer electrode film 102, a silicon oxide film 103, a BPSG (Boro Phospho Silicate Glass) film 108, a silicon nitride film 109 and the wiring 24 are laminated in the stated order, on an upper surface of a silicon substrate 100 in the Z-axis direction. Note that the transfer electrode film 102 is made of polysilicon. The wiring 24 is made of aluminum or an aluminum alloy. The field insulating film 101 is a silicon oxide film.

A tungsten film 107 is inserted between the silicon oxide film 103 and the BPSG film 108 in the Z-axis direction. The tungsten film 107 is connected to the transfer electrode film 102 by means of lower contact plugs A. Also, the tungsten film 107 is connected to the wiring 24 by means of upper contact plugs B. As shown in FIG. 3A, the top of the wiring 24 is covered with a passivation film 112 which is a silicon nitride film.

Each lower contact plug A passes through the silicon oxide film 103. As shown by a portion surrounded by a two-dot chain line in FIG. 3A, each lower contact plug A has a titanium silicide film 105 in a position that is at the bottom thereof and is inside the transfer electrode film 102. Also, each lower contact plug A includes a titanium nitride anneal film 104 and a tungsten nitride film 106, both of which are provided for side walls of the silicon oxide film 103. The silicon oxide film 103 has contact holes 103a, and each pair of side walls faces the corresponding contact hole 103a. The titanium nitride anneal film 104 and the tungsten nitride film 106 extend at the bottom of the tungsten film 107 in the Y-axis direction.

Upper contact plugs B pass through the BPSG film 108 and the silicon nitride film 109. Each contact plug B is filled with a titanium nitride film 110 and a tungsten filling 111. The titanium nitride film 110 and the tungsten fillings 111 are connected to the wiring 24. Also, the titanium nitride film 110 is connected to the tungsten film 107 at the bottom of each upper contact plug B. Note that the titanium nitride film 110 functions as a substantial wiring, together with the wiring 24 provided thereon.

Also note that in the wiring region 20 of the solid state imaging device 1, the contact plugs A and B, and other wiring sections do not include any pure metal film made of titanium. Furthermore, the upper contact plugs B do not include any titanium silicide film.

### 3. Structure of Imaging Pixel Region 10

The following describes a structure of the imaging pixels 11 and the vertical transfer units 21 in the imaging pixel region 10, with reference to FIG. 3B.

As shown in FIG. 3B, a photodiode 121 and charge transfer channels 122 are formed in the silicon substrate 100, in the imaging pixel region 10 of the solid state imaging device 1. More specifically, the photodiode 121 and the charge transfer channels 122 are formed in a region of the silicon substrate 100 that has a predetermined depth from an upper main surface thereof in the Z-axis direction. The charge transfer channels 122 are arranged distant from the photodiode 121 in the X-axis direction. The upper surface of the silicon substrate 100 is covered with a gate insulating film 123.

The transfer electrode films 102 are formed on portions of the gate insulating film 123, and extend in a direction orthogonal to the paper surface. Each portion corresponds to a different one of the charge transfer channels 122 in the silicon substrate 100. Also, a reflection prevention film 120, which is a silicon nitride film, is formed on another portion of the gate insulating film 123. The portion corresponds to the photodiode 121. An insulating film 124 and a light-shielding film 125 are laminated in the stated order on a periphery of each transfer electrode film 102. Here, the light-shielding film 125 is made of tungsten, and can be formed through the same process as the tungsten fillings 111 that serve as a contact material of the upper contact plugs B.

Above the silicon substrate 100, an interlayer insulating film 126 and an intralayer lens film 127 that protrudes downward are laminated in the stated order while partially covering the light-shielding film 125 and the reflection prevention film 120. Here, the interlayer insulating film 126 is made of BPSG, and can be formed through the same process as the BPSG film 108 in the wiring region 20.

Furthermore, an interlayer insulating film 128 is laminated on the interlayer insulating film 126, and an intralayer lens film 129 that protrudes upward is laminated on the intralayer lens film 127. First, the intralayer lens film 129 is formed. Then, the interlayer insulating film 128 is formed for planarization. Here, the intralayer lens films 127 and 129 are formed using the plasma CVD method, and are resistant to temperatures lower than 650 degrees Celsius. Note that the intralayer lens film 129 is a silicon nitride film, similarly to the passivation film 112 in the wiring region 20.

A color filter film 130 is formed on the interlayer insulating film 128. A top lens film 131 is formed on the color filter film 130.

Note that the intralayer lens films 127 and 129, which are formed using the plasma CVD method and are resistant to temperatures lower than 650 degrees Celsius, are arranged higher than the lower contact plugs A (see FIG. 3A) in the wiring region 20 with respect to the silicon substrate 100, in the lamination order of the films. A detailed description of the intralayer lens films 127 and 129 is provided below in the manufacturing method thereof. In this context, “higher . . . in the lamination order” does not indicate absolute “higher” in spatial perception, but indicates “higher (i.e., subsequent)” in the lamination order of the films. In other words, “arranged higher . . . in the lamination order” indicates that the intralayer lens films 127 and 129 are arranged “higher” than the lower contact plugs A in the lamination order by being formed after the lower contact plugs A are formed.

### 4. Advantages of Solid State Imaging Device 1

The following describes advantages of the solid state imaging device 1 according to the present embodiment, with reference to FIGS. 3A and 3B.

As shown in FIG. 3A, according to the solid state imaging device 1 of the present embodiment, the lower contact plugs A in the wiring region 20 do not include any titanium film as a contact material. Instead, each lower contact plug A includes the titanium nitride anneal film 104, the tungsten nitride film 106, and the tungsten film 107. The titanium nitride anneal film 104, the tungsten nitride film 106, and the tungsten film 107 are high melting point metal films. Also, the titanium silicide film 105 is formed at the bottom of each contact hole 103a, and is connected to the transfer electrode film 102 that is made of polysilicon. This lowers contact resistance between the titanium silicide film 105 and the transfer electrode film 102. The use of the titanium silicide film 105 formed at the bottom of each contact hole 103a can lower contact resistance by means of reduction and silicidation of titanium. The titanium silicide film 105 is also useful in lowering resistance when the wirings and the contact plugs are reduced in size.

The upper contact plugs B do not include any titanium film as a contact material. Instead, each upper contact plug B includes the titanium nitride film 110 and the tungsten filling 111. The titanium nitride film 110 and the tungsten fillings 111 are made of high melting point metals. The wiring 24 is made of aluminum or an aluminum alloy, which is a metal as well. Therefore, a contact resistance between the wiring 24 and the titanium nitride film 110 is low, and similarly, a contact resistance between the wiring 24 and the tungsten fillings 111 is low.

According to the present embodiment, the wiring region 20 has such a structure as described above. Therefore, in a case where contact resistance is set according to the prior art, the number of contact plugs to be formed can be reduced. As a result, the size of a chip can be reduced as well.

Also, in the solid state imaging device 1 according to the present embodiment, the titanium silicide film 105 is formed at the bottom of each contact hole 103a. Also, neither the lower contact plugs A nor the upper contact plugs B include any titanium film. This prevents hydrogen from being trapped at the time of an anneal treatment in a gas atmosphere such as hydrogen. As a result, in the solid state imaging device 1, dangling bonds generated (i) at the interface between the silicon substrate 100 and the field insulating film 101 and (ii) at the interface between the silicon substrate 100 and the gate insulating film 123 during the manufacturing process can be effectively terminated by an anneal treatment in a hydrogen atmosphere. This ensures reduction in the interface state density. Accordingly, the solid state imaging device 1 according to the present embodiment achieves high device performance.

Also, in the solid state imaging device 1 according to the present embodiment, the intralayer lens films 127 and 129 in the imaging pixel region 10 are formed using the plasma CVD method and are resistant to temperatures lower than 650 degrees Celsius. However, the intralayer lens films 127 and 129 are selectively formed above the lower contact plugs A in the wiring region 20 in the lamination direction of the films. In other words, during the manufacturing process, the intralayer lens films 127 and 129 are formed after an anneal treatment for forming the titanium silicide film 105 at the bottom of each contact hole 103a. Because of this structure, the intralayer lens films 127 and 129 are not damaged by the anneal treatment performed to form the titanium silicide film 105 at the bottom of each contact hole 103a. Specifically, the intralayer lens films 127 and 129 are formed above the lower contact plugs A in the lamination direction of the films so as to prevent cracks, peeling, and film stress. As a result, the solid state imaging device 1 eliminates problems such as an increase in dark current caused by the damage of the intralayer lens films 127 and 129 in the imaging pixel region 10.

As described above, the solid state imaging device 1 according to the present embodiment lowers contact resistance and suppresses dark current, even when the wirings and the contact plugs are reduced in size.

### 5. Manufacturing Method of Solid State Imaging Device 1

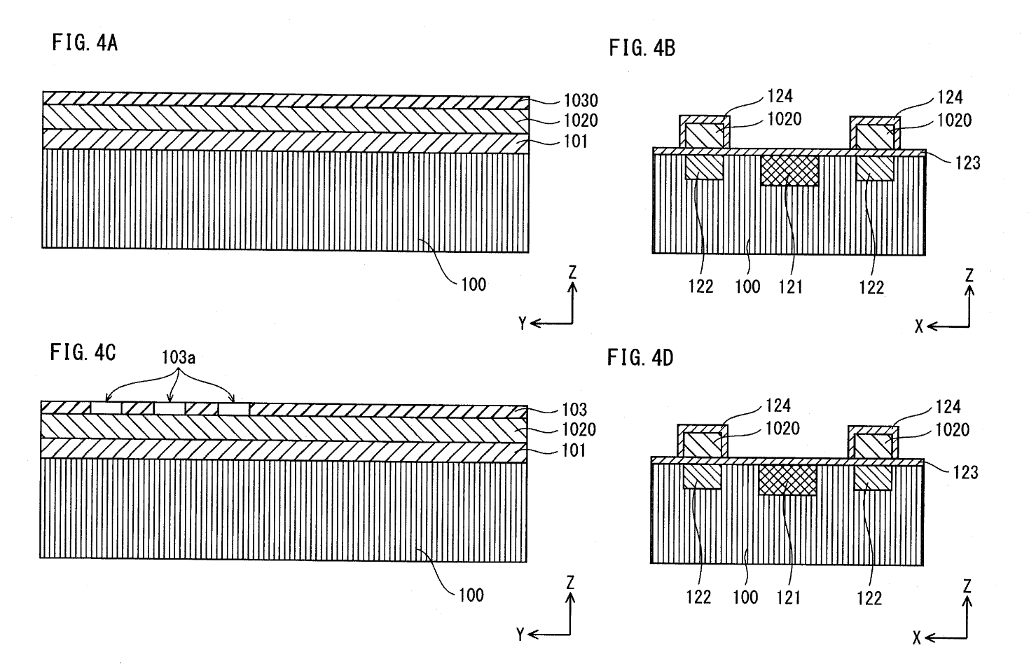

The following describes a manufacturing method of the solid state imaging device 1 according to the present embodiment, with reference to FIGS. 4A to 6D. In particular, the description focuses on characteristic parts of the manufacturing method. Note that the FIGS. 4A and 4C, FIGS. 5A and 5C, and FIGS. 6A and 6C each show a part of the wiring region 20 pertaining to the following description, and FIGS. 4B and 4D, FIGS. 5B and 5D, and FIGS. 6B and 6D each show a part of the imaging pixel region 10 pertaining to the following description.

As shown in FIG. 4A, the field insulating film 101, a transfer electrode preparation film 1020, and a silicon oxide film 1030 are laminated in the stated order on an upper surface of the silicon substrate 100 in the Z-axis direction. The field insulating film 101 is a silicon oxide film, and the transfer electrode preparation film 1020 is made of polysilicon.

Meanwhile, as shown in FIG. 4B, after the gate insulating film 123 is formed in the imaging pixel region 10, impurities are doped into the silicon substrate 100 with use of the gate insulating film 123 as a buffer layer. In this way, the photodiode 121 and the charge transfer channels 122 are formed in a surface region of the silicon substrate 100. Then, the transfer electrode preparation film 1020 is formed to extend on portions of the gate insulating film 123 that correspond to the charge transfer channels 122. The surface of the extended portions of the transfer electrode preparation film 1020 is covered with the insulating film 124.

Then, as shown in FIG. 4C, the contact holes 103a are formed in the silicon oxide film 1030 (silicon oxide film 103). At this time, the imaging pixel region 10 is not subjected to any process, as shown in FIG. 4D.

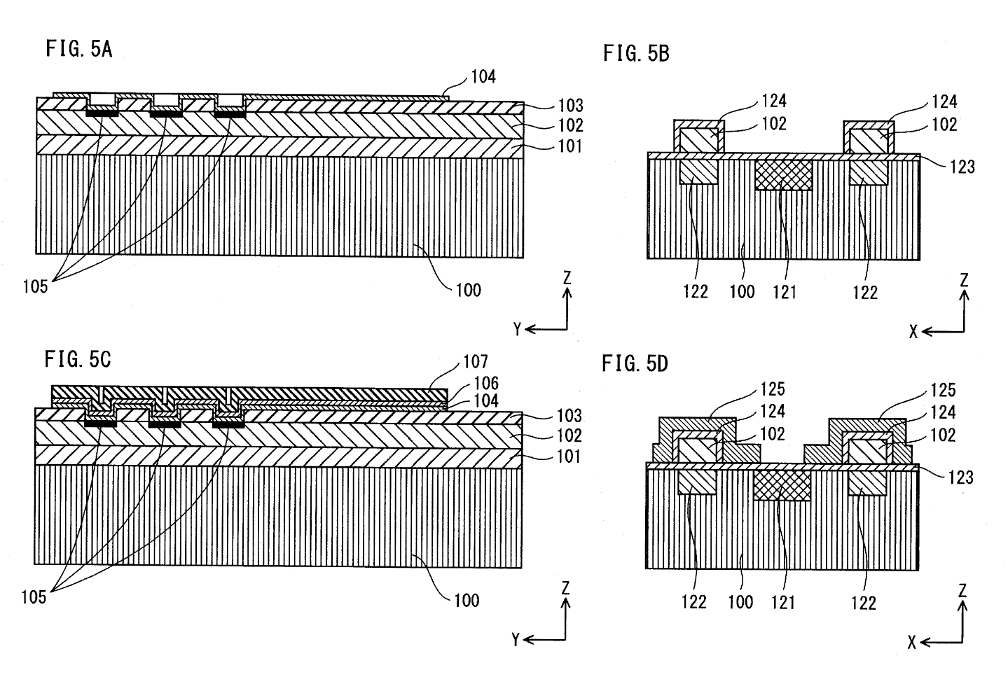

As shown in FIG. 5A, a titanium film having a thickness of 20 nm, for example, is formed on the silicon oxide film 103 and on the inner surface of each contact hole 103a. Then, the titanium film is subjected to an anneal treatment using FA (Furnace Annealing) at the temperature of 650 degrees Celsius for 30 minutes or longer. Note that the anneal treatment is not limited to FA. For example, it is possible to use RTA (Rapid Thermal Annealing). In this way, all of the titanium is consumed and eliminated by silicidation and nitridation. As a result, the titanium film at the bottom of each contact hole 103a turns into the titanium silicide film 105, and the rest turns into the titanium nitride anneal film 104.

As shown in FIG. 5B, films to be arranged higher than the insulating film 124 have not been formed yet at the time the anneal treatment is performed for silicidation and nitridation. This means that the imaging pixel region 10 does not include any film whose heat resistance is lower than 650 degrees Celsius. Specifically, such films having low heat resistance refer to the intralayer lens films 127 and 129, which are formed using the plasma CVD method (see FIG. 3B). The intralayer lens films 127 and 129 have not been formed yet at the time of the anneal treatment. Accordingly, films having low heat resistance, such as the intralayer lens films 127 and 129, are not damaged by the anneal treatment.

Next, as shown in FIG. 5C, the tungsten nitride (WNx) film 106 having a thickness of 25 nm is laminated on the titanium nitride anneal film 104 using a sputtering method, for example. Then, the tungsten film 107 having a thickness of 40 nm is laminated on portions of the tungsten nitride film 106 using the sputtering method, and the tungsten film 107 having a thickness of 50 nm is laminated on the remaining portions of the tungsten nitride film 106 using the CVD method. Afterward, patterning is performed using photolithography and etching so as to form the lower contact plugs A and the intermediate wiring layer made of a high melting metal.

As shown in FIG. 5D, the light-shielding film 125 is formed to cover the surface of the insulating film 124 during the process of forming the tungsten film 107 using the sputtering method and the CVD method.

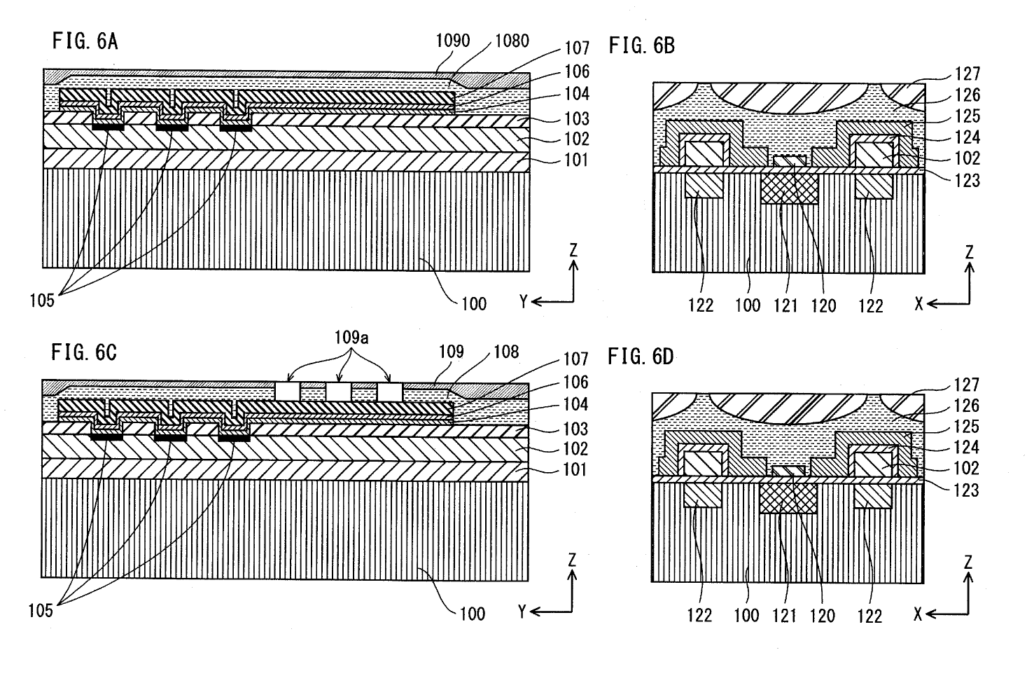

Then, as shown in FIG. 6A, a BPSG film 1080 is formed by depositing BPSG on the tungsten film 107 that has been patterned and reflowing the BPSG. Then, a silicon nitride film 1090 is formed on the BPSG film 1080 using the plasma CVD method. Note that the silicon nitride film 1090 is formed by planarization using a resist and further planarization using an etch-back method.

Note that although the BPSG film 1080 and the silicon nitride film 1090 are formed as lamination films in the present embodiment, other films such as a silicon oxide film and a silicon oxynitride film may be formed instead of the BPSG film 1080 and the silicon nitride film 1090. Also, the method for forming films does not always need to be the plasma CVD method, but an atmospheric pressure CVD method or a low pressure CVD device may be used instead. Furthermore, in the present embodiment, the etch-back method is employed as an example of a planarization technique. However, it is possible to use a CMP (Chemical Mechanical Polishing) method or the like.

Note that as shown in FIG. 6B, the interlayer insulating film 126 is formed when the BPSG film 1080 is formed. Also, the intralayer lens film 127 is formed when the silicon nitride film 1090 is formed. Therefore, the plasma CVD method is also used for the formation of the intralayer lens film 127.

Next, as shown in FIG. 6C, a plurality of contact holes 109a, which pass through the BPSG film 1080 and the silicon nitride film 1090, are formed (the BPSG film 108 and the silicon nitride film 109). The contact holes 109a are used to form the upper contact plugs B. As shown in FIG. 6D, the imaging pixel region 10 is not subjected to any process while the contact holes 109a are being formed.

Subsequently, the titanium nitride film 110 is formed using the sputtering method, and the tungsten fillings 111 are formed using the CVD method. After the titanium nitride film 110 and the tungsten fillings 111 are planarized using the etch-back method or the CMP method, the wiring 24 made of aluminum is laminated on the titanium nitride film 110 and the tungsten fillings 111 (see FIG. 3A).

Note that the interlayer insulating film 128, the intralayer lens film 129, the color filter film 130, and the top lens film 131 are formed after the wiring 24 is formed (see FIG. 3B). Here, the intralayer lens film 129 is, for example, a silicon nitride film, and includes a function as a passivation film.

Although not employed in the present embodiment, it is possible, if desired, to form only a downwardly protruded intralayer lens film, only an upwardly protruded intralayer lens film, or an optical waveguide instead of an intralayer film.

### Embodiment 2

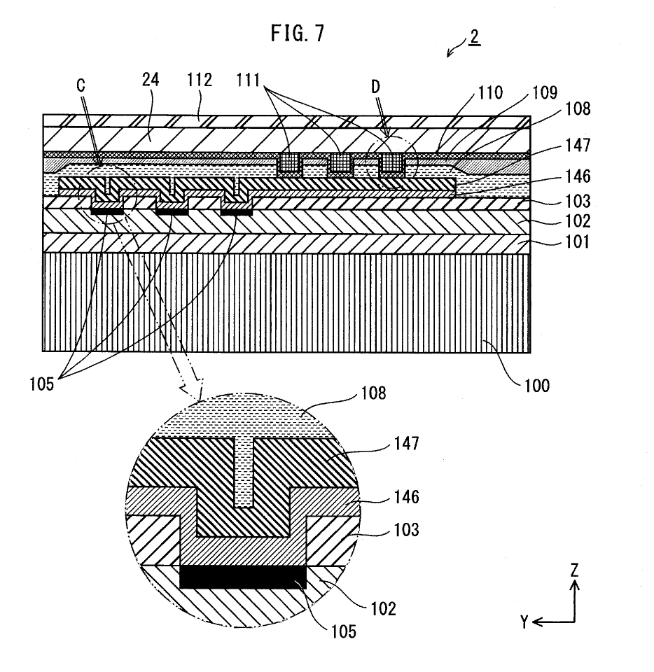

The following describes a structure of a solid state imaging device 2 according to Embodiment 2, with reference to FIG. 7. FIG. 7 is a schematic sectional view corresponding to FIG. 3A. The following mainly describes differences from Embodiment 1 described above.

As shown in FIG. 7, in the solid state imaging device 2 according to the present embodiment, the titanium silicide film 105 is formed at the bottom of the contact hole of each lower contact plug C, similarly to the solid state imaging device 1 according to Embodiment 1 described above. However, each lower contact plug C includes two layers as the contact materials thereof, i.e., a tungsten nitride film 146 and a tungsten film 147 (see the portion surrounded by the two-dot chain line in FIG. 7). In other words, according to the present embodiment, a titanium nitride anneal film is not formed after the titanium silicide film 105 is formed by the anneal treatment during the manufacturing process. Instead, the tungsten nitride film 146 and the tungsten film 147 are formed after unreacted titanium that has not been silicided (hereinafter “non-silicided titanium”) is removed.

In the case of removing non-silicided titanium as described in the present embodiment, another process needs to be added for the removal of the titanium. However, the present embodiment has the following advantage. Assume here that a heat treatment for silicidation is not performed appropriately, resulting in the titanium not being consumed thoroughly by silicidation and nitridation. Even in such a case, the remaining titanium is removed according to the present embodiment. This eliminates a problem of hydrogen being trapped at the time of an anneal treatment that is subsequently performed in a gas atmosphere such as hydrogen. Therefore, the structure of the solid state imaging device 2 according to the present embodiment includes the advantage of more reliably reducing the interface state density between the silicon substrate 100 and each of the field insulating film 101 and the gate insulating film 123, in addition to the advantages of the solid state imaging device 1 according to Embodiment 1 described above.

Note that processing from forming the titanium silicide film 105 to removing non-silicided titanium can be performed as follows.

After forming a titanium film having a thickness of 20 nm, an anneal treatment is performed on the titanium film at the temperature of 650 degrees Celsius for 30 seconds using rapid thermal annealing (RTA). This causes titanium to be consumed by silicidation. However, since some titanium remains unconsumed, the film is dipped in a mixed aqueous solution containing ammonia and hydrogen peroxide for 10 minutes. In this way, non-silicided titanium is selectively removed by etching.

In a case where the contact resistance is desired to be further lowered, an anneal treatment may be further performed at the temperature of 900 degrees Celsius for 30 seconds so that a crystal structure of the titanium silicide film 105 is transitioned from the C49 phase to the C54 phase.

Other structures of the solid state imaging device 2 according to the present embodiment are the same as those of the solid state imaging device 1 according to Embodiment 1. The solid state imaging device 2 according to the present embodiment, which reliably removes non-silicided titanium, has the following advantages in addition to the advantages of the solid state imaging device 1 according to Embodiment 1. That is, the solid state imaging device 2 according to the present embodiment eliminates the problem of hydrogen being trapped at the time of an anneal treatment that is subsequently performed in a gas atmosphere such as hydrogen, and effectively reducing the interface state density between the silicon substrate 100 and each of the field insulating film 101 and the gate insulating film 123.

### Others

As described above, the solid state imaging device 1 according to Embodiment 1 includes the contact plugs A and B, and the solid state imaging device 2 according to Embodiment 2 includes the contact plugs C and D, so that drive pulses are applied to the transfer electrode film 102 in each vertical transfer unit 21. However, the present invention is not limited to such. For example, the present invention is applicable to the following: contact plugs formed by using a shunt wiring technique to lower the resistance of the transfer electrode film 102 of each vertical transfer unit 21; contact plugs for the gate electrodes of the horizontal transfer unit 22 and the output amplifier 23; contact plugs for a floating diffusion; and other contact plugs for the silicon substrate.

Also, according to Embodiments 1 and 2 described above, the titanium silicide film 105 is employed as an example of a metal silicide film. However, it is possible to employ a different film including a high melting point metal, such as cobalt or nickel. Specifically, it is possible to employ a cobalt silicide film or a nickel silicide film.

Also, according to Embodiments 1 and 2 described above, the wirings 24 are made of aluminum or an aluminum alloy. However, it is possible to use copper or a copper alloy instead. Even in such a case, the same advantageous effects as described above are obtained.

### INDUSTRIAL APPLICABILITY

The present invention is useful in realizing a solid state imaging device that lowers contact resistance and suppresses dark current, even when wirings and contact plugs are reduced in size.

### REFERENCE SIGNS LIST

1, 2 solid state imaging device
10 imaging pixel region
11 imaging pixel
20 wiring region
21 vertical transfer unit
22 horizontal transfer unit
23 output amplifier
24 wiring
25 electrode pad
100 silicon substrate
101 field insulating film
102 transfer electrode film
103, 1030 silicon oxide film
104 titanium nitride anneal film
105 titanium silicide film
106, 146 tungsten nitride film
107, 147 tungsten film
108, 1080 BPSG film
109, 1090 silicon nitride film
110 titanium nitride film
111 tungsten filling
112 passivation film
120 reflection prevention film
121 photodiode
122 charge transfer channel
123 gate insulating film
124 insulating film
125 light-shielding film
126, 128 interlayer insulating film
127, 129 intralayer lens film
130 color filter film
131 top lens film
1020 transfer electrode preparation film

1. A solid state imaging device having, with respect to a silicon substrate, a pixel region and a peripheral region adjacent thereto, wherein
the pixel region includes:
a plurality of photoelectric conversion units formed in the silicon substrate; and
a plurality of layers laminated on the silicon substrate, and
the peripheral region includes:
a layer including silicon formed above the silicon substrate;
a plurality of insulating layers formed above the layer including silicon; and
a wiring layer made of a metal material and formed above the insulating layers, wherein
the wiring layer and either one of the silicon substrate and the layer including silicon are connected to each other by a contact plug group passing through the insulating layers,
the contact plug group includes first and second contact plugs, the first contact plug located closer to the silicon substrate than the second contact plug,
the first contact plug is a filling that is disposed in a first contact hole, and that is made of a first contact material,
the second contact plug is a filling that is disposed in a second contact hole, and that is made of a second contact material,
the first contact material includes a metal silicide and a first high melting point metal, the metal silicide formed at a bottom of the first contact plug and including one selected from the group consisting of titanium, cobalt, and nickel,
the second contact material is free of the metal silicide and includes a second high melting point metal,
each of the first and second high melting point metals is other than a pure metal of titanium, cobalt, or nickel,
the plurality of layers in the pixel region include a low heat-resistance layer whose resistance to heat produced by an anneal treatment pertaining to formation of the metal silicide is lower than a predetermined value, and
the low heat-resistance layer is arranged higher than the first contact plug with respect to the silicon substrate.

2. The solid state imaging device of claim 1, wherein
a top of the first contact plug and a bottom of the second contact plug are connected to each other by an intermediate wiring layer provided in parallel with a main surface of the silicon substrate, and
the intermediate wiring layer includes a third high melting point metal that is other than the metal silicide and the pure metal of titanium, cobalt, or nickel.

3. The solid state imaging device of claim 1, wherein
the pixel region further includes:
a plurality of charge transfer channels, each of which is formed adjacent to the corresponding photoelectric conversion unit in the silicon substrate and transfers charge generated by the corresponding photoelectric conversion unit, and
the layer including silicon is a transfer electrode made of polysilicon, and is arranged above each charge transfer channel.

4. The solid state imaging device of claim 1, wherein
each of the first and second high melting point metals includes one selected from the group consisting of tungsten, tungsten nitride, titanium nitride, and annealed titanium nitride.

5. The solid state imaging device of claim 1, wherein
the low heat-resistance layer is resistant to a temperature lower than 650 degrees Celsius.

6. The solid state imaging device of claim 1, wherein
the low heat-resistance layer has been formed using a plasma CVD method.

7. The solid state imaging device of claim 1, wherein
the wiring layer is made of one of aluminum, copper, an aluminum alloy, and a copper alloy.

8. A manufacturing method of a solid state imaging device comprising the steps of:
forming a pixel region that includes a plurality of photoelectric conversion units; and
forming a peripheral region adjacent to a part of the silicon substrate designated for the pixel region, the peripheral region including first and second insulating layers and a wiring layer made of a metal material, wherein
the peripheral region forming step includes:
a first substep of forming the first insulating layer above the silicon substrate and forming a first contact hole in a part of the first insulating layer;
a second substep of forming a titanium layer on an inner surface of the first contact hole;
a third substep of forming a titanium silicide layer at a bottom of the first contact hole by performing an anneal treatment on the titanium layer, and forming a first contact plug by disposing a first high melting point metal in the first contact hole;
a fourth substep of forming the second insulating layer on the first insulating layer in which the first contact plug has been formed, and forming a second contact hole in a part of the second insulating layer that is to be connected to the first contact plug;
a fifth substep of forming a second contact plug by disposing, in the second contact hole, a second high melting point metal including at least one selected from the group consisting of tungsten, tungsten nitride, and titanium nitride; and
a sixth step of forming the wiring layer in contact with the second contact plug,
the pixel region forming step includes:
a substep of forming the plurality of photoelectric conversion units in the silicon substrate; and
a substep of forming a plurality of layers on the silicon substrate after the photoelectric conversion units are formed, the plurality of layers including a low heat-resistance layer whose resistance to heat produced by the anneal treatment in the third substep of the peripheral region forming step is lower than a predetermined value,
the first high melting point metal constituting the first contact plug is free of pure titanium,
the second high melting point metal constituting the second contact plug is free of titanium silicide and pure titanium, and
in the substep of forming the plurality of layers in the pixel region forming step, at least the low heat-resistance layer is formed after the anneal treatment in the third substep of the peripheral region forming step.

9. The manufacturing method of the solid state imaging device of claim 8, wherein
in the third substep of the peripheral region forming step, after forming the titanium silicide layer at the bottom of the first contact hole by the anneal treatment, unreacted titanium that has not been silicided is removed, and at least one of tungsten, tungsten nitride, and titanium nitride is disposed in the first contact hole as a contact material.
